(19) United States
(12) Patent Application Publication
(10) Pub. No.: US 2025/0323605 A1
(43) Pub. Date: Oct. 16, 2025

(54) BIASING CIRCUIT WITH OFFSET CORRECTION AND HIGH-SPEED INPUT STAGE BREAKDOWN PROTECTION

(71) Applicant: MACOM Technology Solutions Holdings, Inc., Lowell, MA (US)

(72) Inventors: Abdelrahman H. AHMED, Lowell, MA (US); Ariel Leonardo VERA VILLARROEL, Lowell, MA (US); Thanh PHAM, Lowell, MA (US); Cristiano BAZZANI, Lowell, MA (US)

(21) Appl. No.: 19/174,741

(22) Filed: Apr. 9, 2025

Related U.S. Application Data
(60) Provisional application No. 63/632,229, filed on Apr. 10, 2024.

(51) Int. Cl. H03F 1/30; H03F 3/45

(52) U.S. Cl. CPC H03F 1/302; H03F 3/45475; H03F 2200/375

(57) ABSTRACT

Circuits, semiconductor devices, and systems are provided. An illustrative circuit includes a first blocking capacitor coupled to an input of an amplifier and a second blocking capacitor coupled to the input of the amplifier, where the first blocking capacitor and the second blocking capacitor provide at least some Direct Current (DC) blocking to the amplifier. The circuit further includes one or more transistors that operate as an emitter follower for the amplifier and a biasing circuit to provide bias control and offset compensation for the amplifier, where the biasing circuit further provides a breakdown protection for the one or more transistors.

### CROSS-REFERENCE TO RELATED APPLICATION

This application claims the benefit of U.S. Provisional Application No. 63/632,229 filed Apr. 10, 2024, the entire contents of which is incorporated herein by reference in its entirety.

### FIELD OF THE DISCLOSURE

The present disclosure is generally directed toward circuits and, in particular, toward amplifier circuits, driver circuits, and biasing circuits.

### BACKGROUND

High speed communication circuits optimize each of their component's voltages and current consumption for optimal power efficiency. Interconnection of different components often requires an adaptation between voltage domains. One way to implement such adaptation is to utilize Alternating Current (AC) coupling (e.g., Direct Current (DC) blocking) of the information signals. On-chip DC blocking capacitor (C) simplifies the assembly and complexity of the system; however, performance specifications must be maintained. An increasingly important specification is the Low-Cutoff Frequency (LFC) as low frequency content in the signal may cause DC wander and reduced signal to noise ratio (SNR), impacting overall system performance.

To guarantee a low value LFC, the capacitor should form a filter (e.g., a Resistive Capacitive (RC) filter) where the resistive component has a high value to satisfy:

$$LFCtarget = 1 / ( 2 * pi * R * C )$$

To satisfy the LFC target and because on-chip capacitance must be limited due to silicon area cost and impact of capacitance's own parasitics to the signal path, a high resistance is needed. A high resistance imposes reliability constraints to the first stage of an amplifier made with cascaded gain stages.

### SUMMARY

Embodiments of the present disclosure contemplate solutions to the above-noted challenges. In particular, an on-chip DC blocked amplifier is provided. In some embodiments, the amplifier includes two or more integrated DC blocking capacitors. Moreover, at its input, the amplifier may utilize one or more transistors configured as emitter followers. These transistors can operate at a high frequency and also present a high input impedance to help obtain a low LFC. The high impedance at the base of the transistor(s) causes the transistor(s) to be sensitive to Breakdown Voltage Collector-Emitter Open Base (BVCEO).

According to at least some embodiments of the present disclosure, a biasing circuit is contemplated to provide the correct biasing of the amplifier (e.g., including bias control and offset compensation). The biasing circuit may also provide breakdown protection of the transistor(s) included at the input of the amplifier.

In some embodiments, a circuit is provided that includes: a first blocking capacitor coupled to an input of an amplifier; a second blocking capacitor coupled to the input of the amplifier, where the first blocking capacitor and the second blocking capacitor provide at least some DC blocking to the amplifier input(s); one or more transistors that operate as an emitter follower for the amplifier; and a biasing circuit to provide bias control and offset compensation for the amplifier, where the biasing circuit further provides a breakdown protection for the one or more transistors.

In some embodiments, a semiconductor device is provided that includes: an amplifier comprising; a first blocking capacitor; a second blocking capacitor, where the first blocking capacitor and the second blocking capacitor provide at least some DC blocking to the amplifier input(s); one or more transistors that operate as an emitter follower for the amplifier; and a biasing circuit to provide bias control and offset compensation for the amplifier, where the biasing circuit further provides a breakdown protection for the one or more transistors.

In some embodiments, a system is provided that includes: a first blocking capacitor; a second blocking capacitor, where the first blocking capacitor and the second blocking capacitor provide at least some DC blocking to an amplifier input(s); a first transistor that operates as a first emitter follower for the amplifier; a second transistor that operates as a second emitter follower for the amplifier; a biasing circuit to provide bias control and offset compensation for the amplifier, where the biasing circuit further provides a breakdown protection for the first transistor and the second transistor, where the biasing circuit provides a first fixed current source and a first variable current source to bias the first transistor and wherein the biasing circuit further provides a second fixed current source and a second variable current source to bias the second transistor; and an operational amplifier to control one or both of the first variable current source and the second variable current source, where the operational amplifier comprises one or more inputs that include an emitter voltage of the first transistor and an emitter voltage of the second transistor.

According to at least some embodiments, the circuit, semiconductor device, and/or system may further include additional circuitry (e.g., one or more circuits) to control the collector voltage of the emitter follower transistor(s) based on an average voltage of the emitters of the emitter follower transistor(s).

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating a communication system according to at least some embodiments of the present disclosure;

FIG. 2 is a block diagram illustrating an amplifier circuit that may be provided as part of transmitter circuit or receiver circuit according to at least some embodiments of the present disclosure;

FIG. 3 illustrates details of a biasing circuit according to at least some embodiments of the present disclosure;

FIG. 4 illustrates additional details of a biasing circuit and one example implementation of an averaging circuit and voltage shifter circuit according to at least some embodiments of the present disclosure;

FIG. 5 illustrates additional details of a biasing circuit and another example implementation of a biasing and breakdown protection circuit according to at least some embodiments of the present disclosure;

FIG. 6A illustrates a normalized collector-emitter voltage (VCE) of a transistor in an amplifier without breakdown protection;

FIG. 6B illustrates a normalized VCE of a transistor in an amplifier with breakdown protection implemented according to at least some embodiments of the present disclosure;

FIG. 7 illustrates frequency response curves with and without utilization of the proposed AC coupling according to at least some embodiments of the present disclosure;

FIG. 8 illustrates a normalized Monte Carlo simulation with and without offset cancellation enabled according to at least some embodiments of the present disclosure; and

FIG. 9 illustrates a method of configuring and operating an amplifier according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing amplifier circuits, driver circuits, and/or equalizer circuits.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with high speed communications over copper or fiber, it should be appreciated that the claims are not limited to high speed electrical and optical or EO communications. Indeed, the biasing circuit(s) depicted and described herein may be utilized in any number of applications utilizing an amplifier (e.g., transmitter applications, receiver applications, filtering applications, etc.). Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

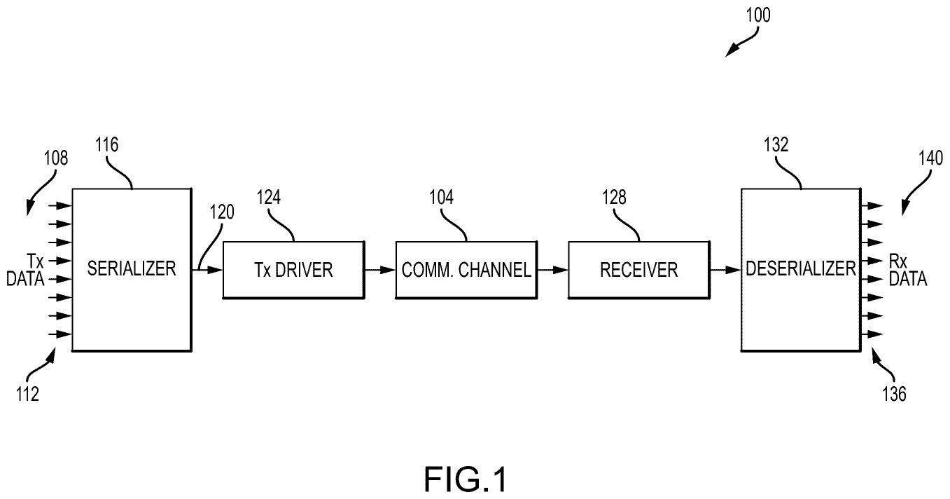

Referring initially to FIG. 1, an illustrative communication system 100 will be described in accordance with at least some embodiments of the present disclosure. The system 100 represents but one possible environment of use of the innovation(s) disclosed herein. As shown, data to be transmitted, referred to as transmit data 108 is provided over two or more parallel paths 112 to a serializer 116. The serializer 116 converts the data received from the two or more parallel paths 112 to a serial stream of data on serial data path 120. The serial stream of data is presented to a transmitter driver 124 which amplifies the signal to a level suitable for transmission over a communication channel 104.

The communication channel 104 may include or correspond to any suitable type of communication channel, such as a channel used for high-speed data transmission. The communication channel 104 may correspond to or include one or more optical fibers. The communication channel 104 may alternatively or additionally correspond to or include one or more electrically-conductive lines such as PCB traces, coaxial cables, connectors. Thus, the data transmitted by the transmitter driver 124 may include an optical signal and/or electrical signal. In one embodiment, the communication channel 104 is length of fiber, which may span in length from few meters to tens of kilometers. However, the method and apparatus disclosed herein may be used for channels of any length or type, such as but not limited to, fiber channels, circuit board traces, coaxial cables, or wired channels, all of which may be any suitable length.

After passing through the communication channel 104, the data is presented to a receiver circuit 128. The receiver circuit 128 may include one or more gain stages. The transmitter driver 124 may include one or more drivers. The transmitter driver 124 and/or receiver circuit 128 may be provided with one or more amplifier circuits comprising one or more biasing circuits as depicted and described herein. The transmitter driver 124 and/or receiver circuit 128 may also include one or more equalizer circuits. The equalizer(s) may be configured to reduce the signal attenuating effects of the communication channel 104.

After equalization, the data is provided to a deserializer 132 which converts the serial data stream to a parallel data path on the two or more data paths 136. The data output by the deserializer may be regarded as received data 140 that can be processed by a communication device that includes the receiver circuit 128 and deserializer 132.

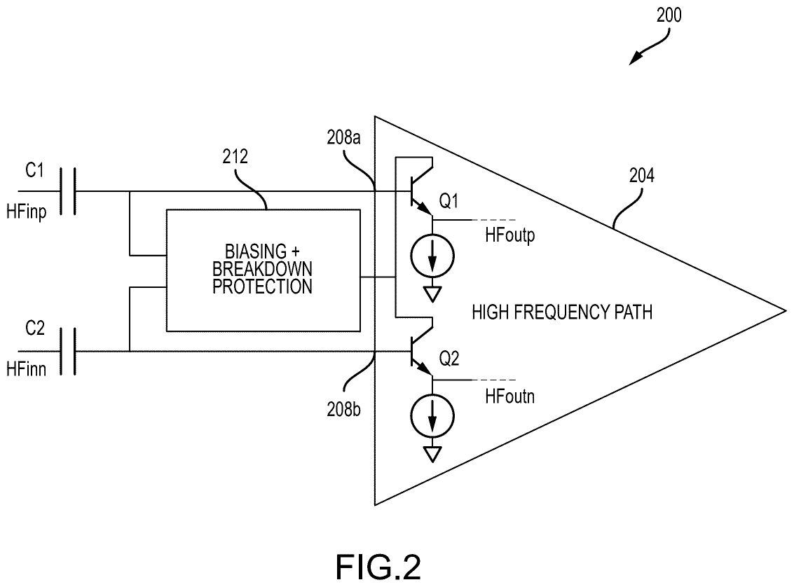

Referring now to FIGS. 2-5, various types of circuit 200 configurations that may be used in connection with a communication system 100 will be described in accordance with at least some embodiments of the present disclosure. As a non-limiting example, the circuit 200 may be provided as part of the transmitter driver 124 that is used to amplify a signal prior to transmission of the signal on the communication channel 104.

FIG. 2 illustrates an example circuit 200 comprising an amplifier 204 having a first input 208a and a second input 208b. The first input 208a may be directly connected to a first capacitor C1. The second input 208b may be directly connected to a second capacitor C2. While not depicted, the amplifier 204 may include a greater or lesser number of inputs. In some embodiments, the first input 208a and second input 208b may be configured to receive high-frequency input signals (e.g., a first high-frequency input HFinp and second high-frequency input HFinn).

The amplifier 204 may be configured to provide one or more high-frequency outputs based on the processing of the high-frequency input(s). The output of the amplifier 204 may include a first high-frequency output HFoutp and a second high-frequency output HFoutn.

In some embodiments, the capacitors C1, C2 may be integrated into the amplifier 204. In some embodiments, the capacitors C1, C2 may be provided external to the amplifier 204. The circuit 200 may be configured to achieve LFC targets on the order of approximately 10 kHz, 100 kHz, 1 MHz, or 10 MHz. In such an application, the capacitors C1, C2 may be on the order of one or two pF to tens of pF.

Moreover, at its input, the amplifier 204 may comprise one or more transistors (e.g., a first transistor Q1 and a second transistor Q2) configured as emitter followers. The transistor(s) Q1, Q2 may be configured to operate at relatively high frequencies (e.g., broadband frequencies on the order of 10 GHz up to 100 GHz). Thus, the inputs provided to the amplifier 204 may have frequency content as large as 10 GHz to 100 GHz. The transistors Q1, Q2 may also present a high input impedance, which helps obtain a low LFC.

The biasing circuit 212 may be provided to correct biasing of the amplifier 204 and to provide breakdown protection for the transistors Q1, Q2. In some embodiments, the biasing circuit 212 may be configured to provide biasing control and offset compensation for the amplifier 204 in addition to further providing breakdown protection for the transistors Q1, Q2. As shown in FIG. 2, the biasing circuit 212 may be connected between both capacitors C1, C2 and both transistors Q1, Q2.

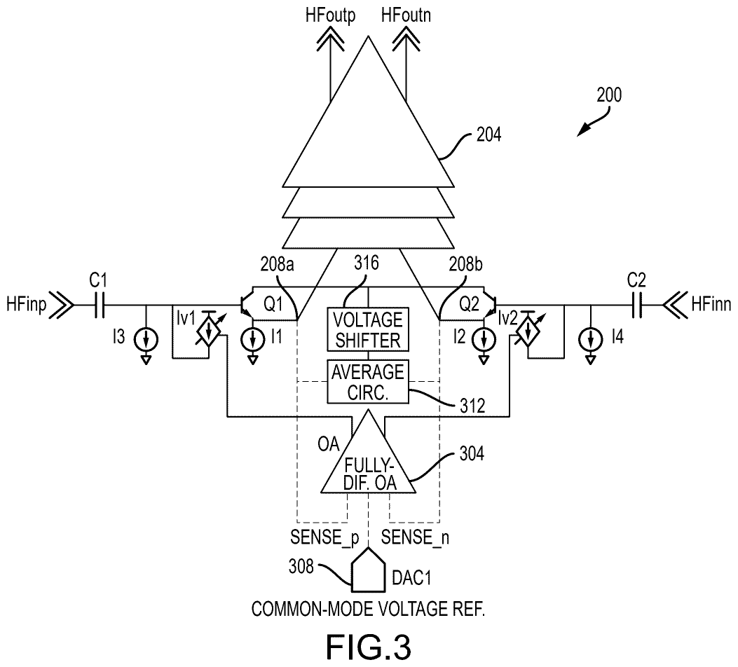

FIGS. 3-5 illustrate additional details of a biasing circuit 212 and components thereof in accordance with at least some embodiments of the present disclosure. In the configuration of FIG. 3, biasing of each transistor Q1, Q2 is achieved using a fixed current source and a variable current source for each transistor Q1, Q2. More specifically, and in accordance with at least some embodiments of the present disclosure, the biasing circuit 212 may include a first fixed current source 13 and a second fixed current source 14. The biasing circuit 212 may also include a first variable current source Iv1 and a second variable current source Iv2. The first fixed current source 13 and the first variable current source Iv1 may be configured to bias the first transistor Q1. Similarly, the second fixed current source 14 and the second variable current source Iv2 may be configured to bias the second transistor Q2. The variable current sources Iv1, Iv2 may substantially regulate current at the node common with the fixed current sources 13, 14, respectively, and the base of the transistor Q1, Q2.

Since the emitter follower provided by each transistor Q1, Q2 is biased with a fixed current source 11, 12 at its emitter node, the variable current source Iv1, Iv2 defines the base voltage and emitter voltage. A fully differential operational amplifier (OA) 304 may be used to control the variable current sources Iv1, Iv2. In accordance with at least some embodiments, the OA 304 inputs sense the emitter voltages Sense_p, Sense_n of the transistors Q1, Q2, respectfully. The OA 304 may also receive a common-mode voltage reference as an input from a first Digital-to-Analog Converter (DAC) DAC1 308. The output of the OA 304 may provide two functions: (1) matching the common-mode voltage value of the two input signals Sense_p, Sense_n to the common-mode voltage reference controlled via DAC1 308 and (2) eliminating the differential mode voltage difference (e.g., the offset is cancelled at the inputs of the OA 304).

Moreover, and in accordance with at least some embodiments of the present disclosure, the inputs to the OA 304 can be averaged by an averaging circuit 312, then that voltage may be shifted with a voltage shifter 316 and used as the input to each transistors' Q1, Q2 collector voltages. In this way, changes in the emitter voltage are tracked at the collectors, maintaining the Collector-Emitter voltage (VCE) of the transistors Q1, Q2. A first additional fixed current source 13 may also be connected between the base of the first transistor Q1 and ground while a second additional fixed current source 14 may be connected between the base of the second transistor Q2 and ground. The additional fixed current sources 13, 14 may be configured to regulate the base voltage of the transistors Q1, Q2, respectively.

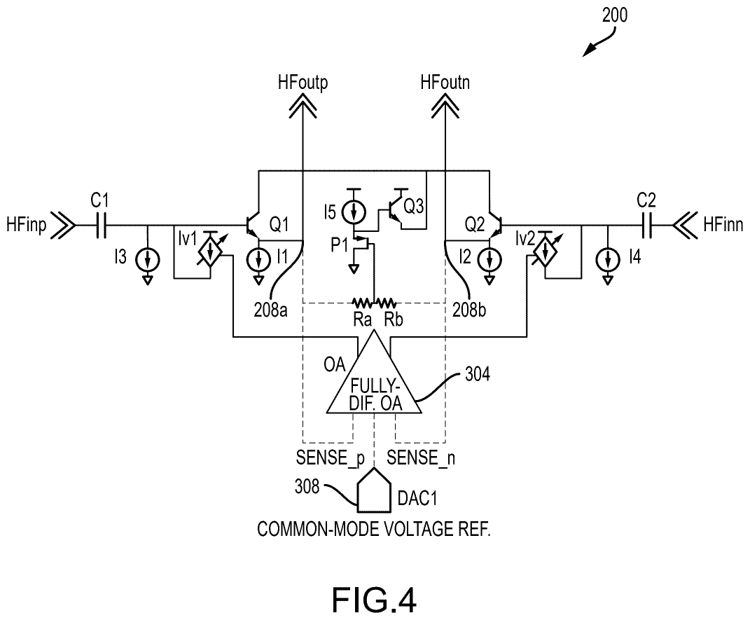

FIG. 4 illustrates a first possible implementation of the averaging circuit 312 in accordance with at least some embodiments of the present disclosure. The averaging circuit 312 is shown to include a first resistor Ra and second resistor Rb connected between the emitters of the transistors Q1, Q2. The resistors Ra, Rb may be used to extract the common-mode voltage by implementing a virtual ground between their interconnection when Ra substantially equals Rb.

The obtained common-mode voltage may then be shifted using a transistor (e.g., a PFET transistor P1) connected between the resistors Ra, Rb as a source-follower. Finally, the shifted voltage is used to set a base voltage of a shifting transistor Q3, whose emitter is connected to collectors of the transistors Q1, Q2. In this configuration, a change in the emitter common-mode voltage is translated to a proportional change at Q1, Q2 collector voltages. A fifth fixed current source 15 may also be connected between the PFET transistor P1 and the shifting transistor Q3, to properly bias transistor P1 as a source-follower.

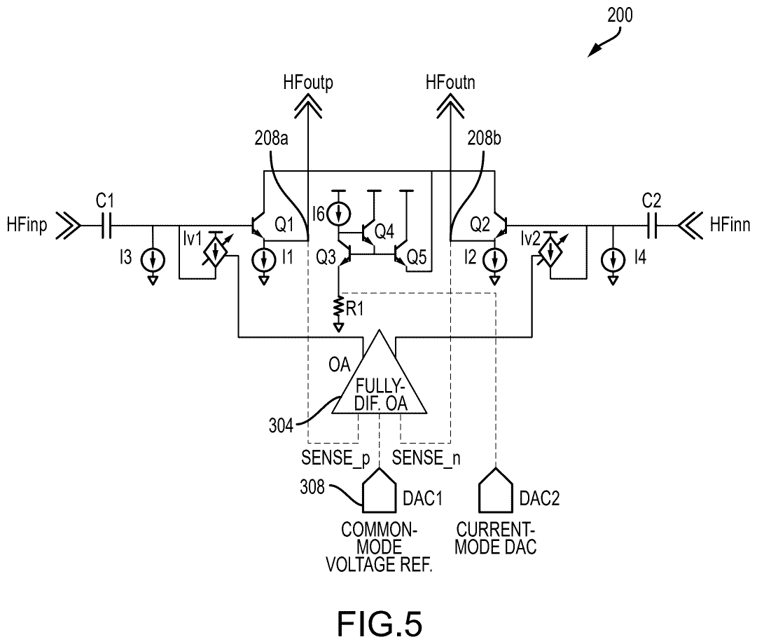

FIG. 5 illustrates another possible implementation of the biasing and breakdown protection circuit in accordance with at least some embodiments of the present disclosure. In the illustrated configuration, a fifth transistor Q5 sets the collector voltage for the first and second transistors Q1, Q2. The fifth transistor Q5 may also track an emitter voltage of a third transistor Q3. A fourth transistor Q4 may be provided between the third transistor Q3 and fifth transistor Q5. The fourth transistor Q4 may be configured to reduce the error introduced by the base current of the third transistor Q3 and fifth transistor Q5.

In accordance with at least some embodiments, the emitter voltage of the fifth transistor Q5 may be set by a resistor R1 and a fixed current source I6 combined with current from current-mode DAC2 (e.g., voltage at Q3-emitter=(I6+DAC2)*R1). This constitutes a replica voltage that replaces the need for the averaging circuit while providing proper biasing and breakdown protection. In some embodiments, the output of the second DAC2 could be a copy of DAC1 output, such the number of DACs reduce (e.g., for power and area savings).

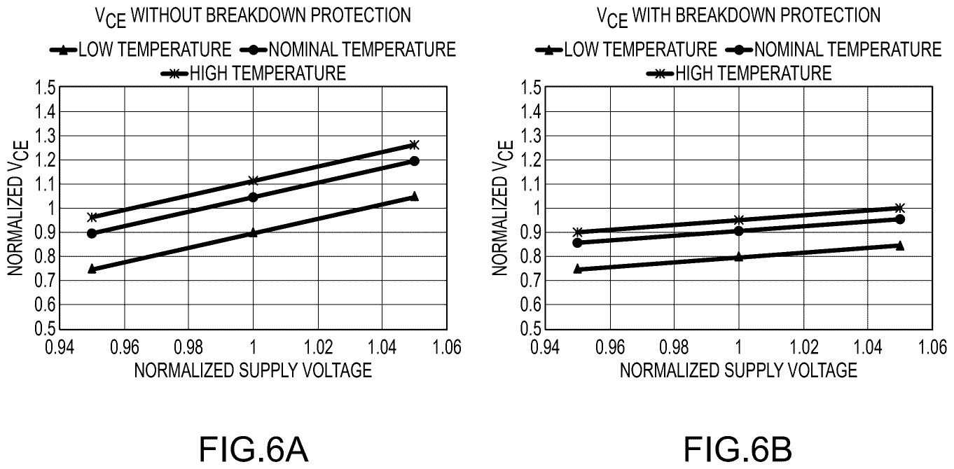

With reference now to FIGS. 6A and 6B, the impact of voltage and temperature variations on the operation of transistors Q1, Q2 is illustrated. In the figures, the y-axis corresponds to the collector-emitter voltage of each transistor Q1, Q2 normalized to its BVCEO value. FIG. 6A illustrates that the transistors Q1, Q2 are under stress at nominal and high temperatures and nominal and high supply voltages. This implementation could reduce the supply voltage to avoid the stress voltage; however, other performance metrics (e.g., bandwidth or linearity) will be affected by this change.

FIG. 6B, on the other hand, illustrates results obtained when a proposed solution of the present disclosure is implemented (e.g., when breakdown protection is provided with a biasing circuit 212). In accordance with at least some embodiments, the stress on transistors Q1, Q2 may be kept below its limit across all voltage and temperature operation corners. Overall, the transistors Q1, Q2 are not placed under unnecessary stress and their VCE variation is substantially minimized.

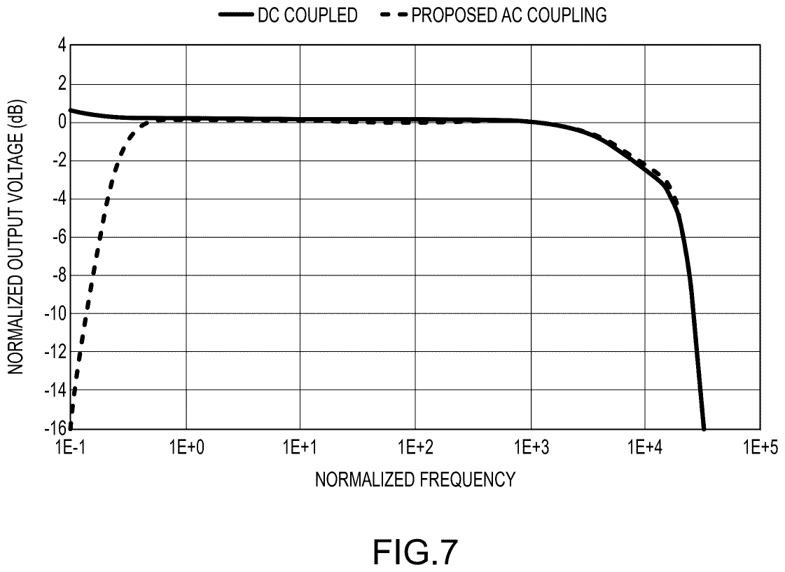

FIG. 7 illustrates the frequency response of a circuit design incorporating a biasing circuit 212 in accordance with embodiments of the present disclosure and a circuit design not incorporating a biasing circuit 212. Specifically, FIG. 7 compares the frequency response of the two designs (e.g., with and without the biasing circuit 212). The output voltage gain is normalized to its value at the normalized frequency of 1 (1E+0). The solid line illustrates the frequency response when the on-chip DC blocking capacitors C1, C2 are not implemented, consequently, the low frequency gain goes to lower frequencies; however, this design will require off-chip blocking capacitors.

The dashed line illustrates the frequency response when on-chip DC blocking capacitors C1, C2 are used according to embodiments of the present disclosure. As can be seen in FIG. 7, the frequency response above the target LFC (e.g., 1E0) remains unchanged, satisfying the target LFC frequency response.

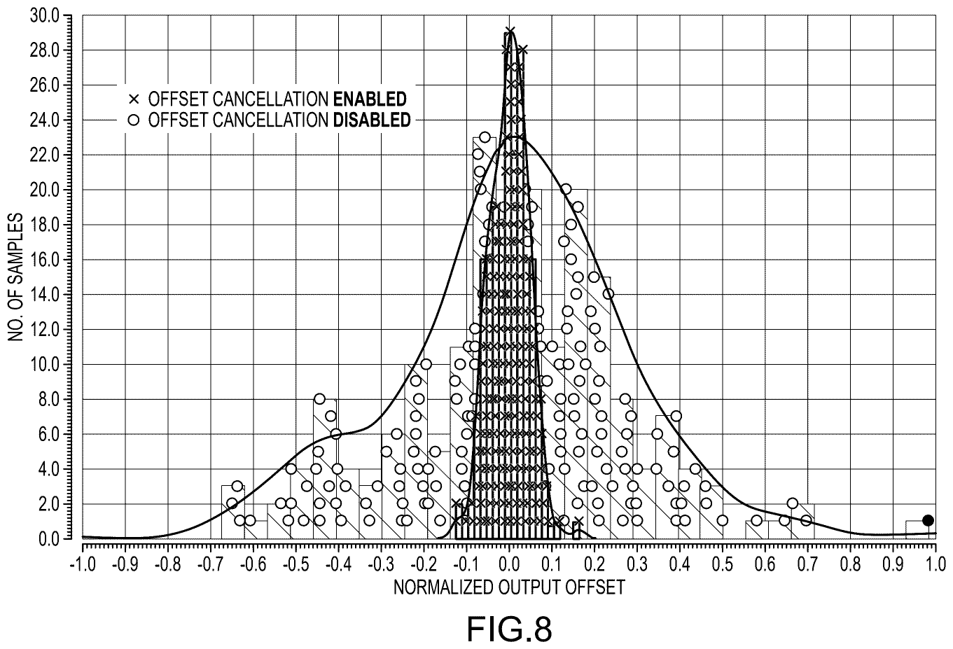

Referring now to FIG. 8, a normalized Monte Carlo simulation is illustrated. In this simulation, the process is varied to reflect the post-fabrication performance. When offset cancellation is disabled, the offset increases. Conversely, enabling the offset cancellation circuit 200 reduces the offset below 0.2 of the maximum value predicted by the variation distribution.

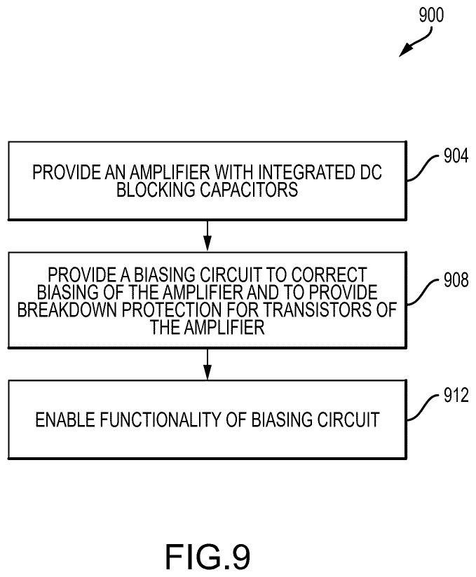

Referring now to FIG. 9, a method 900 will be described in accordance with at least some embodiments of the present disclosure. The method 900 begins by providing an amplifier 204 with integrated DC blocking capacitors (e.g., capacitors C1, C2) (step 904).

The method 900 further includes providing a biasing circuit 212 to correct biasing of the amplifier 204 and to provide breakdown protection for transistors Q1, Q2 of the amplifier 204 (step 908). The functionality of the biasing circuit 212 may, in some embodiments, be enabled or disabled, depending upon whether functionality of the biasing circuit 212 is desired for an application in which the amplifier 204 it deployed (step 912).

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A circuit, comprising:
a first blocking capacitor coupled to an input of an amplifier;
a second blocking capacitor coupled to the input of the amplifier, wherein the first blocking capacitor and the second blocking capacitor provide at least some Direct Current (DC) blocking to the amplifier;
one or more transistors that operate as an emitter follower for the amplifier; and
a biasing circuit to provide bias control and offset compensation for the amplifier, wherein the biasing circuit further provides a breakdown protection for the one or more transistors.

2. The circuit of claim 1, wherein the one or more transistors comprise a first transistor and a second transistor.

3. The circuit of claim 2, wherein the biasing circuit provides a first fixed current source and a first variable current source to bias the first transistor and wherein the biasing circuit further provides a second fixed current source and a second variable current source to bias the second transistor.

4. The circuit of claim 3, further comprising:
an operational amplifier to control one or both of the first variable current source and the second variable current source.

5. The circuit of claim 4, wherein the operational amplifier comprises a fully differential operational amplifier.

6. The circuit of claim 4, wherein the operational amplifier comprises one or more inputs that include an emitter voltage of the first transistor and an emitter voltage of the second transistor.

7. The circuit of claim 6, wherein the operational amplifier receives a second input from a Digital-to-Analog Converter (DAC), wherein the second input comprises a common-mode voltage reference, and wherein the operational amplifier substantially matches a common-mode voltage value of the one or more inputs to the second input.

8. The circuit of claim 7, wherein the one or more inputs are averaged by an averaging circuit.

9. The circuit of claim 8, wherein the averaging circuit comprises one or more resistors to extract the common-mode voltage value of the one or more inputs.

10. The circuit of claim 9, wherein the averaging circuit comprises at least one transistor to shift the common-mode voltage value.

11. The circuit of claim 8, wherein the averaging circuit is replaced by a voltage reference generated from a second DAC and a constant current.

12. The circuit of claim 1, wherein the one or more transistors comprise a first transistor and a second transistor, wherein a base of the first transistor is connected directly to the first blocking capacitor, and wherein a base of the second transistor is connected directly to the second blocking capacitor.

13. A semiconductor device, comprising:
an amplifier comprising;
a first blocking capacitor;
a second blocking capacitor, wherein the first blocking capacitor and the second blocking capacitor provide at least some Direct Current (DC) blocking to the amplifier;
one or more transistors that operate as an emitter follower for the amplifier; and
a biasing circuit to provide bias control and offset compensation for the amplifier, wherein the biasing circuit further provides a breakdown protection for the one or more transistors.

14. The semiconductor device of claim 13, wherein the one or more transistors comprise a first transistor and a second transistor.

15. The semiconductor device of claim 14, wherein the biasing circuit provides a first fixed current source and a first variable current source to bias the first transistor and wherein the biasing circuit further provides a second fixed current source and a second variable current source to bias the second transistor.

16. The semiconductor device of claim 15, further comprising:
an operational amplifier to control one or both of the first variable current source and the second variable current source.

17. The semiconductor device of claim 16, wherein the operational amplifier comprises one or more inputs that include an emitter voltage of the first transistor and an emitter voltage of the second transistor.

18. The semiconductor device of claim 17, wherein the operational amplifier receives a second input from a Digital-to-Analog Converter (DAC), wherein the second input comprises a common-mode voltage reference, and wherein the operational amplifier substantially matches a common-mode voltage value of the one or more inputs to the second input.

19. The semiconductor device of claim 18, wherein the one or more inputs are averaged by an averaging circuit, wherein the averaging circuit comprises one or more resistors to extract the common-mode voltage value of the one or more inputs, and wherein the averaging circuit comprises at least one transistor to shift the common-mode voltage value.

20. A system, comprising:
a first blocking capacitor;
a second blocking capacitor, wherein the first blocking capacitor and the second blocking capacitor provide at least some Direct Current (DC) blocking to an amplifier;
a first transistor that operates as a first emitter follower for the amplifier;
a second transistor that operates as a second emitter follower for the amplifier;
a biasing circuit to provide bias control and offset compensation for the amplifier, wherein the biasing circuit further provides a breakdown protection for the first transistor and the second transistor, wherein the biasing circuit provides a first fixed current source and a first variable current source to bias the first transistor and wherein the biasing circuit further provides a second fixed current source and a second variable current source to bias the second transistor; and
an operational amplifier to control one or both of the first variable current source and the second variable current source, wherein the operational amplifier comprises one or more inputs that include an emitter voltage of the first transistor and an emitter voltage of the second transistor.
